(19) United States
(12) Patent Application Publication
(10) Pub. No.: US 2024/0355657 A1
(43) Pub. Date: Oct. 24, 2024

(54) HOLDING PLATE, HOLDING SYSTEM, USE OF THE HOLDING PLATE, USE OF THE HOLDING SYSTEM AND PROVISIONING METHOD

(71) Applicant: ASMPT GmbH & Co. KG, Munich (DE)

(72) Inventors: Christoph OECKL, Munich (DE); Martin NEUSSER, Munich (DE)

(21) Appl. No.: 18/636,673

(22) Filed: Apr. 16, 2024

(30) Foreign Application Priority Data
Apr. 19, 2023 (DE) 10 2023 109 858.6

(51) Int. Cl. H01L 21/673; B23Q 1/03

(52) U.S. Cl. CPC H01L 21/67333; B23Q 1/03

(57) ABSTRACT

A holding plate for providing components to a pick and place machine comprises at least two support devices for vertically supporting carrier plates for components in a predetermined horizontal position, a limiting device per support device for horizontally limiting the respective carrier plate, wherein the holding plate has a pin holding volume for at least partially holding pins of the components inserted through the carrier plate, and wherein the holding plate comprises at least one fastening device for fastening the respective carrier plate.

The present invention relates to a holding plate for providing electronic components to a pick and place machine. Furthermore, the present invention relates to a holding system for providing electronic components to a pick and place machine. The invention also relates to a use of the holding plate, a use of the holding system and a provisioning method for providing electronic components to a pick and place machine by means of a holding plate.

The currently publicly known options for providing electronic components to a pick and place machine usually include belt conveyors, magazines, bar magazines, trays and/or special conveyors. These are usually designed to provide a specific type of electronic component and/or a specific electronic component. Holding plates for holding and providing various electronic components are known in particular for small series and/or prototype population. These holding plates are usually manufactured individually and are therefore very time-consuming and/or costly and usually have no and/or limited possibilities for reuse.

It is therefore the object of the present invention to eliminate or at least partially eliminate the disadvantages in the prior art described above. In particular, it is the object of the invention to provide a holding plate for providing electronic components to a pick and place machine, with which provision, in particular of various electronic components, to a pick and place machine is made particularly easy. In particular, it is further the object of the invention to provide a holding system for providing electronic components to a pick and place machine, a use of the holding plate, a use of the holding system and a provisioning method for providing electronic components to a pick and place machine by means of a holding plate.

The object set out above is achieved by the claims. In particular, the object is achieved by a holding plate having the features of the independent claim 1. Furthermore, the object is achieved by a holding system with the features of independent claim 8, by a use of the holding plate with the features of independent claim 13, by a use of a holding system with the features of independent claim 14 and by a provisioning method with the features of independent claim 15. Further advantages and details of the invention emerge from the dependent claims, the description and the drawings. Features and details that are described in connection with the holding plate according to the invention naturally also apply in connection with the holding system according to the invention, the use of the holding plate according to the invention, the provisioning and vice versa in each case, such that reciprocal reference is or can always be made with respect to the disclosure of individual aspects of the invention.

According to a first aspect of the invention, the object is achieved by a holding plate for providing electronic components to a pick and place machine, the holding plate comprising at least two support devices for vertically supporting in each case at least one carrier plate for electronic components in a predetermined horizontal position on a support plane, at least one limiting device per support device for horizontally limiting the respective carrier plate in the predetermined horizontal position, each support device together with the respective at least one limiting device forming a carrier plate holding volume for holding at least one carrier plate in the predetermined horizontal position on the support plane, wherein the holding plate has, for each carrier plate holding volume, a pin holding volume adjacent below the respective carrier plate holding volume and the support plane for at least partially holding pins of the electronic components inserted through the carrier plate, and wherein the holding plate comprises, for each carrier plate holding volume, at least one fastening device for fastening the respective carrier plate in the respective carrier plate holding volume.

The basic core idea of the holding plate is to enable different carrier plates to be held. The carrier plates are designed to provide electronic components. By holding carrier plates, the holding plate can be used and reused for at least two carrier plates with preferably different electronic components. The carrier plates used are preferably of a modular design. For example, the carrier plates have the same outer dimensions and/or the dimensions are designed as modular multiples of each other, in particular in two spatial axes. The carrier plates are designed, for example, as printed circuit boards and/or plastic sheets for holding electronic components. The carrier plates are preferably designed as printed circuit boards in a standard dimension, for example a standard industry dimension of 44 mm×94 mm. The carrier plates are preferably designed to hold only three to ten electronic components, in particular a plurality of electronic components. The carrier plates preferably have a layout and/or drill holes for electronic components of different sizes and/or designs.

The design of the holding plate and the carrier plates advantageously simplifies the programming of the pick and place machines and/or the production devices for the carrier plates, as equal and/or uniform spacing is preferably used.

The electronic components are preferably held and provided by the carrier plates by inserting and/or at least in sections inserting the electronic components into and/or through a carrier plate. These types of carrier plates are easy, inexpensive and/or quick to manufacture. The holding plate according to the invention enables different holding plates to be held and thus various electronic components to be provided by simple and cost-effective means due to the at least two carrier plate holding volumes. In the context of the invention, the at least two carrier plate holding volumes are preferably to be understood as positioning devices for the carrier plates. The at least two support plate holding volumes are formed by the at least two support devices and the at least two limiting devices. Due to the carrier plate holding volumes, the carrier plates can preferably be arranged in a defined and/or repeatable manner at and/or on the holding plate. The at least two carrier plate holding volumes preferably each have an extension that corresponds to an extension of at least one carrier plate or essentially at least one carrier plate. The phrase “X or substantially X” is to be understood in the context of the invention as a possible minor deviation, for example due to manufacturing tolerances, material and/or process properties, without changing the underlying, intended function of the feature.

The at least two support devices are each designed to vertically support at least one carrier plate for electronic components in a predetermined horizontal position on a support plane. The at least one limiting device per support device is designed to horizontally limit the respective support plate in the predetermined horizontal position. The at least two support devices and the at least two limiting devices form the at least two support plate holding volumes. A carrier plate holding volume is preferably formed by exactly one limiting device and exactly one support device. The support plane is preferably located at, on and/or in the holding plate.

In the context of the invention, it is assumed that the holding plate and the carrier plates are in a horizontal position during use and the arrangement details and the relative proportions of the devices to one another are preferably to be understood accordingly.

The at least two carrier plates can be fastened in the carrier plate holding volume with at least one fastening device. In the context of the invention, each carrier plate has its own fastening device and/or at least two carrier plates have a common fastening device. In a simple possible embodiment, the fastening devices are designed as a screw connection, for example, whereby a screw device is screwed into the holding plate and the screw head protrudes into at least one carrier plate holding volume and/or over at least one carrier plate and fastens it. To put it clearly, the at least one fastening device is preferably designed for fastening at least one carrier plate to the holding plate. The fastening device preferably comprises screw devices, swivel devices, plug-in and/or clip connections.

The holding plate is particularly advantageous because a pin holding volume is adjacent to each carrier plate holding volume, at least in sections. The underside of the respective pin holding volume is adjacent to the corresponding support plate holding volume and the support plane. The adjacency of the pin holding volume below the respective carrier plate holding volume is to be understood as the arrangement of the pin holding volume on a side of the carrier plate holding volume facing the underside of the holding plate. The at least two pin holding volumes are used to hold at least sections of the pins of the electronic components. The electronic components usually have pins protruding from the electronic component, for example in the form of contacts. The electronic components are preferably inserted through the carrier plate with these contacts to hold and/or arrange the electronic components, so that the contacts protrude on an underside of the carrier plate. For advantageous placement of the carrier plate in the holding plate, the pin holding volumes therefore provide space for the pins of the electronic components.

The holding plate is preferably plate-shaped, in particular cuboid. The carrier plates can preferably be arranged parallel to a main extension plane of the holding plate in the carrier plate holding volume. The main extension plane of the holding plate is preferably to be understood as the two-dimensional plane of the largest extension of the holding plate. The carrier plates can preferably be inserted along an insertion axis on and/or into the carrier plate holding volume, in particular with the insertion axis being arranged orthogonally to the main extension plane of the holding plate.

The holding plate is preferably designed for insertion into and/or onto a standard carrier device for feeding to a pick and place machine. The holding plate is preferably fed to a pick and place machine by the carrier device and serves the pick and place machine as a multiple area magazine for the simple and cost-effective feeding of different electronic components in small quantities. The electronic components can be advantageously removed and/or picked up from the carrier device and from the holding plate by the pick and place machines. Due to the design and the interchangeable carrier plates, the holding plate can be advantageously reused with the same or other carrier plates. The holding plate according to the invention thus enables advantageous component provision, for example for small series, product improvements and prototype board population. The design of the holding plate, in particular the pin holding volume, ensures that the components are fed to the pick and place machines without tilting or changing position.

A holding plate designed in this way is particularly advantageous, as it enables electronic components to be provided to a pick and place machine by simple and cost-effective means, wherein the holding plate can be reused for different combinations of electronic components and carrier plates.

According to a preferred further development of the invention, it may be provided in a holding plate that a respective horizontal extension of the at least two pin holding volumes corresponds to at least 50%, in particular at least 75%, 85% or at least 95%, of a horizontal extension of the respective carrier plate holding volume. The at least two pin holding volumes each have an extension that corresponds to at least 50% of a respective extension of the at least two carrier plate holding volumes. The extension of the at least two pin holding volumes and the at least two carrier plate holding volumes is preferably to be understood in each case in or parallel to the main extension plane of the holding plate. The extension of the carrier plate receiving volumes is preferably to be understood as the holding areas for the respective at least one carrier plate between the limiting devices of the respective carrier plate holding volume. An extension of at least 50%, preferably at least 75%, 85% or at least 95%, of the at least two pin holding volumes in relation to the extension of the at least two carrier plate holding volumes is particularly advantageous, as large pin holding volumes are thus advantageously available for holding the pins of the electronic components, at least in sections. This improves the versatility of the holding plate, as more space is made available to hold the pins of the electronic components, at least in sections, and there are therefore fewer restrictions on the electronic components and/or their arrangement.

According to a preferred further development of the invention, it may be provided in a holding plate that the at least two limiting devices are each designed as at least one projection on and/or as a recess in the holding plate, in particular monolithic and/or firmly bonded. The limiting devices are clearly described as projections at and/or on the holding plate and/or as recesses in the holding plate. The at least two limiting devices enable a defined, repeatable arrangement of the carrier plates on and/or in the holding plate. The design of the at least two limiting devices each as at least one projection is to be understood, for example, as a design of the limiting devices as pins, webs and/or other projections for limiting the arrangement of the carrier plates on the holding plate. The design of the at least two limiting devices each as at least one recess is to be understood, for example, as a milled gap in the holding plate for holding at least one carrier plate. The at least two limiting devices are preferably designed to be monolithic and/or firmly bonded to the holding plate.

The at least two limiting devices advantageously enable a defined and repeatable arrangement of the respective carrier plate parallel to the main extension plane of the holding plate.

A holding plate designed in this way is particularly advantageous due to the design of the at least two limiting devices, as it enables electronic components to be provided to a pick and place machine by simple and cost-effective means, wherein the holding plate can be reused for different combinations of electronic components and carrier plates.

According to a preferred further development of the invention, it may be provided in a holding plate that at least one of the support devices comprises at least one depth positioning device for the defined holding and positioning of the carrier plate. In the context of the invention, a depth positioning device is preferably to be understood as a limitation of the carrier plates in a depth direction, i.e., along the insertion axis described above. The depth positioning device is clearly described as a depth stop below and/or in a support plane for the holding plate, which is held in and/or on the holding plate. The at least one depth positioning device is preferably designed as a positioning edge, in particular a circumferential positioning edge, a positioning lip, a positioning web and/or a depth positioning device designed in some other way. The depth positioning device advantageously enables a defined and repeatable arrangement of the respective carrier plate in a horizontal plane and/or along an axis orthogonal to the main extension plane of the holding plate.

A holding plate designed in this way is particularly advantageous due to the depth positioning device, as it enables electronic components to be provided to a pick and place machine by simple and cost-effective means, wherein the holding plate can be reused for different combinations of electronic components and carrier plates.

According to a preferred further development of the invention, it may be provided in a holding plate that at least one of the carrier plate holding volumes and/or the pin holding volumes is formed in one piece, as a pocket volume and/or as a continuous cut-out in the holding plate. In particular, at least one of the carrier plate holding volumes and/or the pin holding volumes is designed as a pocket volume in the holding plate that is open on at least one side. In the context of the invention, a pocket volume is to be understood as a volume within the holding plate, the pocket volume being limited by the holding plate at least in sections, preferably on several sides. The pocket volume is preferably only open at the top to hold the respective carrier plate and/or the pins of the electronic components in sections. Alternatively, or additionally, at least one of the carrier plate holding volumes and/or the pin holding volumes is designed as a continuous cut-out in the holding plate. A continuous cut-out in the holding plate can be achieved cost-effectively using a cutting process such as water jet or laser cutting, for example. A continuously cut-out carrier plate holding volume preferably has at least one depth positioning device described above for the defined holding and vertical positioning of the respective carrier plate. A holding plate designed in this way is particularly advantageous due to the design of the carrier plate holding volume or the pin holding volume, as it enables electronic components to be provided to a pick and place machine by simple and cost-effective means, wherein the holding plate can be reused for different combinations of electronic components and carrier plates.

According to a preferred further development of the invention, it may be provided in a holding plate that at least one of the pin holding volumes is arranged centrally and/or centered with respect to the respective carrier plate holding volume and/or is evenly spaced from the respective carrier plate holding volume. A central and/or centered arrangement of the pin holding volume in relation to the respective carrier plate holding volume advantageously enables an improved arrangement of the electronic components and/or the carrier plate on and/or in this carrier plate holding volume. This enables and/or improves a versatile use of the holding plate, as a preferred central and/or centered space is made available to hold the pins of the electronic components, at least in sections, and there are therefore fewer restrictions on the electronic components and/or their arrangement. A holding plate designed in this way is particularly advantageous due to the design of the pin holding volume, as it enables electronic components to be provided to a pick and place machine by simple and cost-effective means, wherein the holding plate can be reused for different combinations of electronic components and carrier plates.

According to a preferred further development of the invention, it may be provided in a holding plate that the at least two carrier plate holding volumes and/or limiting devices are rectangular, in particular square, in particular wherein the at least two limiting devices each comprise at least one corner recess and/or that the at least two carrier plate holding volumes are arranged within a common plane, in particular parallel to an underside of the holding plate. The at least two carrier plate holding volumes and/or limiting devices are preferably designed to hold rectangular, preferably square, carrier plates, so that the design and manufacture of the carrier plates is advantageously simplified. The at least two limiting devices preferably comprise corner recesses. The corner recesses allow for an advantageous arrangement and/or positioning of the carrier plates on the sides of the carrier plates. As a result of a holding plate and/or limiting device designed in this way, inaccuracies at the corners of the carrier plates and/or soiling and/or interfering factors in the corners of the limiting devices are advantageously avoided when arranging and/or positioning the carrier plates and/or these do not have a negative effect on the positioning of the carrier plates. Additionally, or alternatively, the at least two corner recesses allow the carrier plate to be removed in an advantageous way, for example by a user. The at least two limiting devices preferably each comprise four corner recesses. A holding plate designed in this way is particularly advantageous due to the at least one corner recess, as it enables electronic components to be provided to a pick and place machine by simple and cost-effective means, wherein the holding plate can be reused for different combinations of electronic components and carrier plates.

According to a preferred further development of the invention, a holding plate may comprise at least one ID device, wherein the ID device is designed for identification and/or position detection of the holding plate by a pick and place machine. The ID device is designed, for example, as a bar code, QR code or other device for identifying and/or detecting the position of the holding plate, in particular in a machine-readable form. The ID device is engraved, lasered into and/or otherwise permanently or interchangeably attached to the holding plate. An ID device advantageously enables the holding plate to be detected by a transport system and/or by the pick and place machines and thus enables the corresponding carrier plates and electronic components to be assigned in an advantageous manner. A holding plate designed in this way is particularly advantageous due to the at least one ID device, as it enables electronic components to be provided to a pick and place machine by simple and cost-effective means, wherein the holding plate can be reused for different combinations of electronic components and carrier plates.

According to a second aspect of the invention, the object is achieved by a holding system for providing electronic components to a pick and place machine. The holding system comprises a holding plate and at least two carrier plates for electronic components. The holding plate is designed according to the first aspect. All the advantages that have already been described for the holding plate according to the first aspect of the invention result from the described holding system. The at least two carrier plates can be fastened in the at least two carrier plate holding volumes of the holding plate by the at least one fastening device in each case.

According to a preferred further development of the invention, it may be provided in a holding system that at least one first carrier plate of the at least two carrier plates is designed to hold different electronic components than a second carrier plate of the at least two carrier plates, in particular, wherein the first carrier plate comprises at least one first plug and socket device for holding a first electronic component and wherein the second carrier plate comprises at least one second plug and socket device for holding a second electronic component, wherein the first plug and socket device and the second plug and socket device are designed differently. The holding system is particularly advantageous if at least two carrier plates have different electronic components and/or if at least two carrier plates have different plug and socket devices for holding different components. The holding system advantageously enables a plurality of carrier plates with different plug and socket devices and thus with different electronic components to be held. The plug and socket devices are preferably designed in the simplest form as holes through the carrier plates to hold the contacts of the electronic components. The plug and socket devices preferably correspond to different arrangements of contacts of the electrical components in order to plug the components into and/or onto the plug and socket devices. To put it clearly, the holding system is designed to hold a plurality of identical and/or different carrier plates, wherein the different carrier plates are each designed to hold different electrical components. A holding system designed in this way is particularly advantageous due to the holding plate and the different carrier plates, as it enables electronic components to be provided to a pick and place machine by simple and cost-effective means, wherein the holding plate can be reused for different combinations of electronic components and carrier plates.

According to a preferred further development of the invention, it may be provided in a holding system that at least one of the at least two carrier plates comprises a support carrier plate, wherein the support carrier plate is fastened at a distance from and to the carrier plate, in particular wherein the support carrier plate has the same plug and socket devices as the carrier plate and/or wherein the support carrier plate has at least one frame device. A support carrier plate on the corresponding carrier plate is particularly advantageous for higher, larger components and/or components at risk of tipping, for example with a high center of gravity. The support carrier plate is preferably fastened to the carrier plate at a distance and, to put it clearly, represents a supporting structure for the electronic components in and/or on the carrier plate. The carrier plate has the same plug and socket devices as the carrier plate and/or is designed as a frame device for supporting the electronic components. In other words, the support carrier plate is a second, supporting plane, wherein the support carrier plate is preferably arranged and fastened parallel to the corresponding carrier plate. The plug and socket devices in the support carrier plate and the corresponding carrier plate are preferably arranged in alignment with each other. The support carrier plate is preferably fastened to the carrier plate with spacer bolts, sleeves and/or spacer devices. The support carrier plate is preferably arranged and fastened on the side of the carrier plate facing away from the pin holding volume. In other words, the support carrier plate is fastened to the carrier plate above the carrier plate. A holding system designed in this way is particularly advantageous due to the at least one support carrier plate, as it enables electronic components to be provided to a pick and place machine by simple and cost-effective means, wherein the holding plate can be reused for different combinations of electronic components and carrier plates.

According to a preferred further development of the invention, it may be provided in a holding system that at least one of the two carrier plates comprises at least one ID device, wherein the ID device is designed for identification and/or position detection of the at least one carrier plate by a pick and place machine. The ID device is designed, for example, as a bar code, QR code or other device for identifying and/or detecting the position of the carrier plate, in particular in a machine-readable form. The ID device is engraved, lasered into and/or otherwise permanently or interchangeably attached to the carrier plate. An ID device advantageously enables the carrier plate to be detected by a transport system and/or by the pick and place machines and thus enables the corresponding electronic components to be assigned in an advantageous manner. A holding system designed in this way is particularly advantageous due to the at least one ID device, as it enables electronic components to be provided to a pick and place machine by simple and cost-effective means, wherein the holding plate can be reused for different combinations of electronic components and carrier plates.

According to a third aspect of the invention, the object is achieved by using a holding plate according to the first aspect for providing electronic components arranged on carrier plates to a pick and place machine for populating substrates with the electronic components. All the advantages that have already been described for the holding plate according to the first aspect of the invention and/or for the holding system according to the second aspect of the invention result from the described use. The use of the holding plate for providing electronic components, which are arranged on carrier plates, to a pick and place machine for populating substrates with the electronic components is particularly advantageous, since the holding plate enables electronic components to be provided to a pick and place machine by simple and inexpensive means, the holding plate being reusable for different combinations of electronic components and carrier plates.

According to a fourth aspect of the invention, the object is achieved by using a holding system for providing electronic components arranged on carrier plates to a pick and place machine for populating substrates with electronic components. The holding system is designed according to the second aspect. In particular, at least one first carrier plate of the at least two carrier plates is designed to hold different electronic components as a second carrier plate of the at least two carrier plates. In particular, the first carrier plate comprises at least one first plug and socket device for holding a first electronic component and the second carrier plate comprises at least one second plug and socket device for holding a second electronic component, wherein the first plug and socket device and the second plug and socket device are designed differently.

All the advantages that have already been described for the holding plate according to the first aspect of the invention and/or for the holding system according to the second aspect of the invention result from the described use. The use of the holding system for providing electronic components, which are arranged on carrier plates, to a pick and place machine for populating substrates with the electronic components is particularly advantageous, since the holding system enables electronic components to be provided to a pick and place machine by simple and inexpensive means, the holding plate being reusable for different combinations of electronic components and carrier plates.

According to a fifth aspect of the invention, the object is achieved by a provisioning method for providing electronic components to a pick and place machine by means of a holding plate. The provisioning method comprises:
providing at least one holding plate according to the first aspect or a holding system according to the second aspect,
populating at least two carrier plates with different electronic components,
inserting the at least two carrier plates into the at least two carrier plate holding volumes of the at least one holding plate,
fastening the at least two carrier plates to the at least two carrier plate holding volumes by at least one fastening device of the holding plate in each case,
providing the electronic components to a pick and place machine through the holding plate.

The provisioning method described has all the advantages already described for the holding plate according to the first aspect of the invention and/or the holding system according to the second aspect of the invention. Populating the at least two carrier plates with different electronic components is preferably to be understood as inserting the pins of the electronic components through and/or immersing the pins of the electronic components at least in sections into the pin holding volume.

Unless explicitly stated otherwise, the method steps described above and below can be carried out individually, together, once, multiple times, at the same time and/or one after the other in any order. A designation as, for example, “first procedural step” and “second procedural step” does not require any chronological order and/or prioritization. A preferred order of the method steps provides that the method steps are carried out in the order listed.

A holding plate according to the invention, a holding system, a use of the holding plate, a use of the holding system and a provisioning method are explained in more detail below on the basis of drawings. Brief description of the schematic drawings:

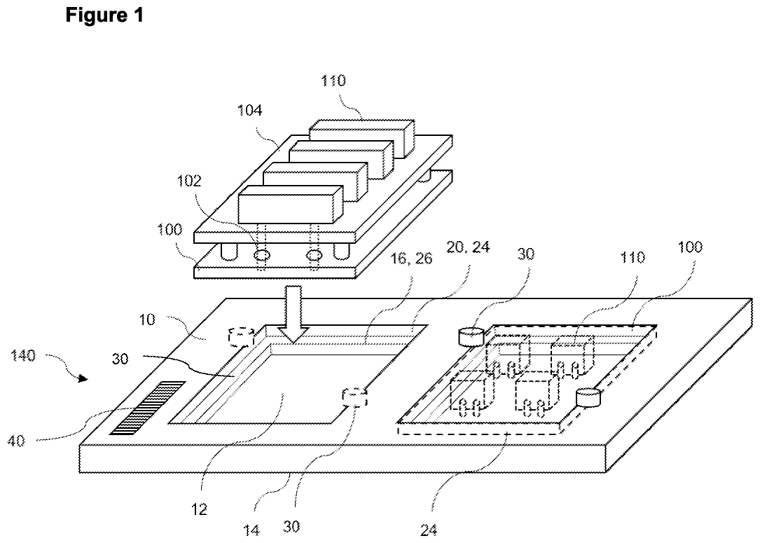

FIG. 1 shows a perspective view of a holding system with a holding plate and two carrier plates for electronic components,

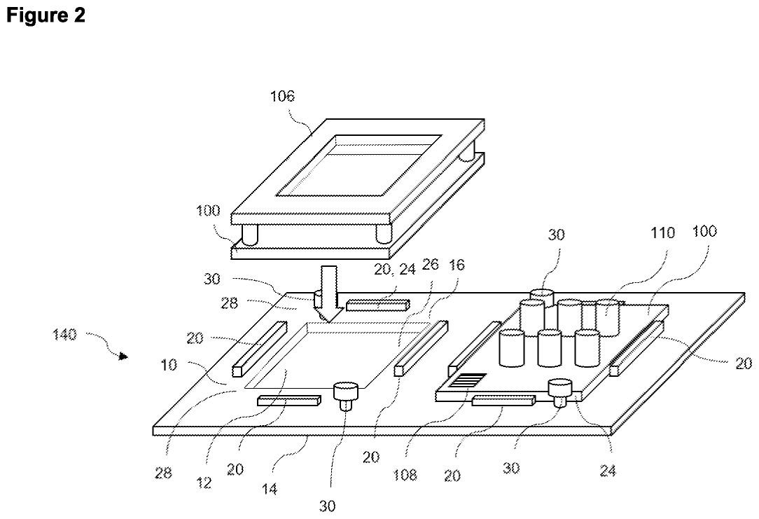

FIG. 2 shows a perspective view of a further holding system with a holding plate and two carrier plates for electronic components,

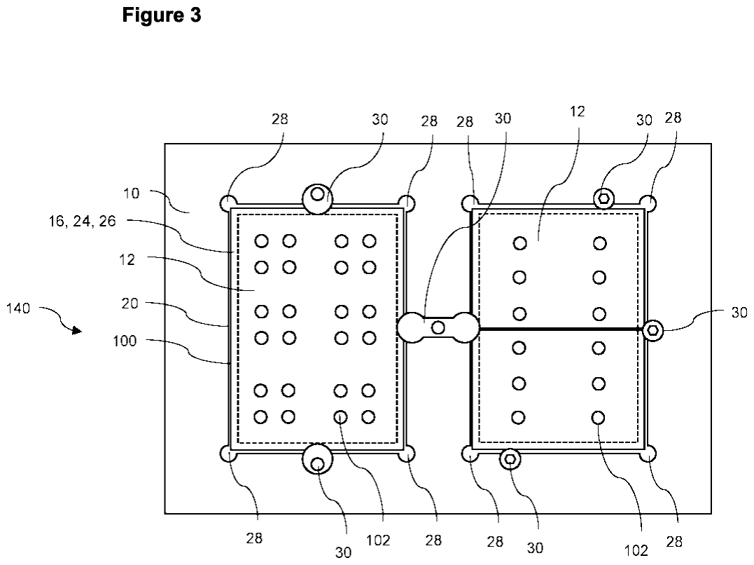

FIG. 3 shows a top view of a further holding system with a holding plate and three carrier plates,

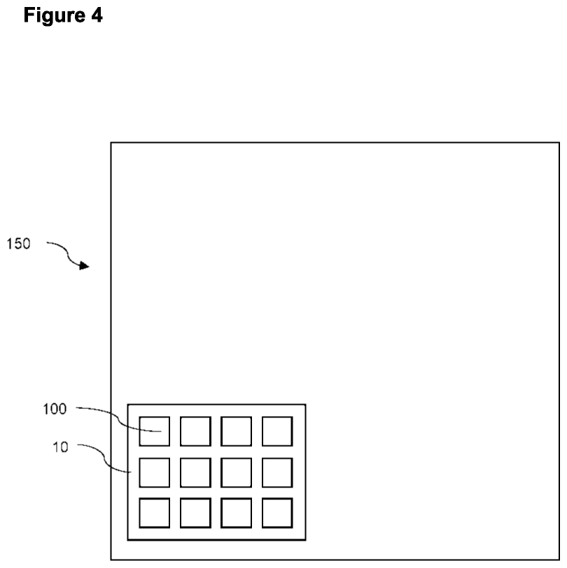

FIG. 4 shows a top view of a pick and place machine with a holding system comprising a holding plate and a plurality of carrier plates, and

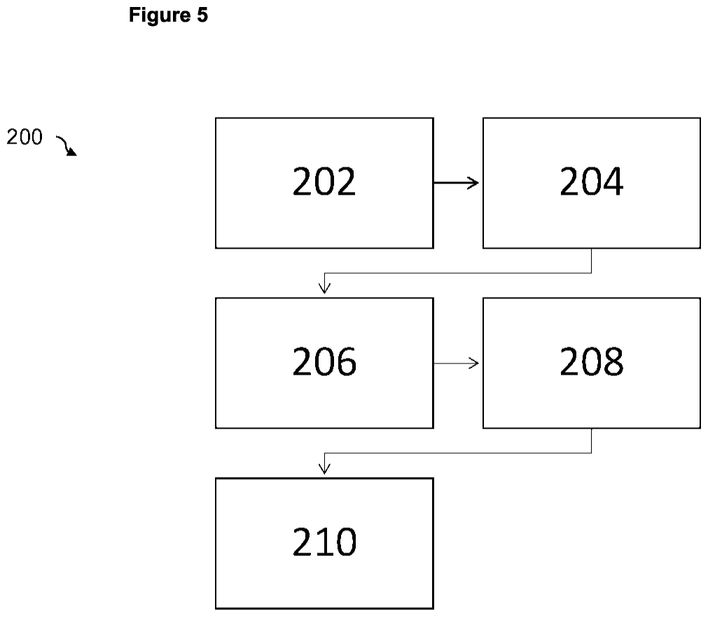

FIG. 5 shows a flow diagram of a design of the provisioning method according to the invention.

Elements with the same function and mode of operation are each provided with the same reference signs in FIGS. 1 to 5.

FIG. 1 shows a schematic perspective view of a holding system 140 with a holding plate 10 and two carrier plates 100 for electronic components 110. The holding plate 10 is designed to provide the electronic components 110 to a pick and place machine 150 (not shown). The holding plate 10 comprises two support devices 22 for vertically supporting in each case one carrier plate 100 for electronic components 110 in a predetermined horizontal position on a support plane 26, in each case one circumferential limiting device 20 per support device 22 for horizontally limiting the respective carrier plate 100 in the predetermined horizontal position, wherein each support device 22 together with the respective one limiting device 20 forms a carrier plate holding volume 24 for holding one carrier plate 100 in the predetermined horizontal position on the support plane 26, wherein the holding plate 10 has, for each carrier plate holding volume 24, a pin holding volume 12 adjacent below the respective carrier plate holding volume 24 and the support plane 26 for partially holding pins of the electronic components 110 inserted through the carrier plate 100, and wherein the holding plate 10 comprises, for each carrier plate holding volume 24, in each case two fastening devices 30 for fastening the respective carrier plate 100 in the respective carrier plate holding volume 24. The two limiting devices 20 are each designed as a recess in the holding plate 10. The carrier plate holding volumes 24 each comprise a depth positioning device 16 in the form of a circumferential positioning lip for defined holding and positioning of the carrier plate 100. The pin holding volumes 12 are in one piece and designed as continuous cut-outs in the holding plate 10. The pin holding volumes 12 are arranged centrally and centered relative to the respective carrier plate holding volumes 24 and are evenly spaced relative to the respective limiting device 20. The two carrier plate holding volumes 24 are arranged within a common plane parallel to an underside 14 of the holding plate 10. The holding plate 10 comprises one ID device 40, wherein the ID device 40 is designed for identification and for position detection of the holding plate 10 by a pick and place machine 150 (not shown). The first carrier plate 100 of the two carrier plates 100 is designed to hold other electronic components 110 than the second carrier plate 100 of the at least two carrier plates 100. The first carrier plate 100 comprises four first plug and socket devices 102 for holding first electronic components 110 and the second carrier plate 100 comprises four second plug and socket devices 102 for holding second electronic components 110, wherein the first plug and socket devices 102 and the second plug and socket devices 102 are designed differently. The left carrier plate 100 includes a support carrier plate 104, the support carrier plate 104 being spaced apart from and fastened to the carrier plate 100, the support carrier plate 104 having the same plug and socket devices 102 as the carrier plate 100.

FIG. 2 shows a schematic perspective view of a further holding system 140 with a holding plate 10 and two carrier plates 100 for electronic components 110. The holding plate 10 is designed to provide the electronic components 110 to a pick and place machine 150 (not shown). The holding plate 10 comprises two support devices 22 for vertically supporting a respective carrier plate 100 for electronic components 110 in a predetermined horizontal position on a support plane 26, a respective circumferential limiting device 20 per support device 22 for horizontally limiting the respective carrier plate 100 in the predetermined horizontal position, each support device 22 together with the respective limiting device 20 forming a carrier plate holding volume 24 for holding a carrier plate 100 in the predetermined horizontal position on the support plane 26. The holding plate 10 comprises four fastening devices 30 for fastening the carrier plates 100 in the two carrier plate holding volumes 24. Each of the four limiting devices 20 per carrier plate holding volume 24 are designed as projections on the holding plate 10 in a monolithic and firmly bonded manner. Each of the limiting devices 20 has four corner recesses 28.

The carrier plate holding volumes 24 each comprise a depth positioning device 16 in the form of a circumferential positioning lip for defined holding and positioning of the carrier plate 100. The left carrier plate 100 includes a support carrier plate 104, the support carrier plate 104 being spaced apart from and fastened to the carrier plate 100, wherein the support carrier plate 104 has a frame device 106. For the sake of greater clarity, the left-hand carrier plate 100 is shown without electronic components 110 and plug and socket devices 102. The right carrier plate 100 comprises one ID device 108, wherein the ID device 108 is designed for identification and for position detection of the carrier plate 100 by a pick and place machine 150 (not shown). The two carrier plate holding volumes 24 are arranged within a common plane parallel to an underside 14 of the holding plate 10.

FIG. 3 shows a top view of a further holding system 140 with a holding plate 10 and three carrier plates 100. The holding plate 10 is designed to provide the electronic components 110 (not shown) to a pick and place machine 150 (not shown). The holding plate 10 comprises two carrier plate holding volumes 24 for holding carrier plates 100. One carrier plate 100 is arranged in the left carrier plate holding volume 24, and two carrier plates 100 are arranged in the right carrier plate holding volume 24. The holding plate 10 comprises six fastening devices 30 for fastening the carrier plates 100 to the holding plate 10 and in the two carrier plate holding volumes 24.

The middle fastening device 30 is used to fasten the three carrier plates 100 together. For the sake of greater clarity, the carrier plates 100 are shown without electronic components 110 (not shown). The two limiting devices 20 and carrier plate holding volumes 24 are rectangular in shape, with the two limiting devices 20 each comprising four corner recesses 28. The first carrier plate 100 comprises a plurality of first plug and socket devices 102 and the second and third carrier plates 100 comprise a plurality of second plug and socket devices 102, wherein the first plug and socket devices 102 and the second plug and socket devices 102 are of different designs.

FIG. 4 shows a schematic top view of a pick and place machine 150 with a holding system 140 with a holding plate 10 and a plurality of carrier plates 100. The pick and place machine 150 is designed for populating substrates with electronic components 110 (not shown) from the holding system 140.

FIG. 5 shows a schematic flow diagram of an embodiment of the provisioning method 200 according to the invention. For improved clarity, only the reference numbers of the method steps are indicated in FIG. 5. In a first process step, the provisioning method 200 comprises providing 202 a holding plate 10 or a holding system 140. In a further process step, the provisioning method 200 comprises populating 204 two carrier plates 100 with different electronic components 110. In a further process step, the provisioning method 200 comprises inserting 206 the two carrier plates 100 into the two carrier plate holding volumes 24 of the holding plate 10. In a further process step, the provisioning method 200 comprises fastening 208 the two carrier plates 10 to the holding plate 10 by a plurality of fastening devices 30 of the holding plate 10 in each case. In a further process step, the provisioning method 200 comprises providing 210 the electronic components 110 to a pick and place machine 150 through the holding plate 10.

### LIST OF REFERENCE SIGNS

10 Holding plate
12 Pin holding volume
14 Underside
16 Depth positioning device
20 Limiting device
22 Support devices
24 Carrier plate holding volume
26 Support plane
28 Corner recesses
30 Fastening device
40 ID device
100 Carrier plate
102 Plug and socket device
104 Support carrier plate
106 Frame device
108 ID device
110 Electronic components
140 Holding system
150 Pick and place machine
200 Provisioning method
202 Providing
204 Populating
206 Inserting
208 Fastening
210 Providing

1. A holding plate for providing electronic components to a pick and place machine, the holding plate comprising at least two support devices for vertically supporting in each case at least one carrier plate for electronic components in a predetermined horizontal position on a support plane, at least one limiting device per support device for horizontally limiting the respective carrier plate in the predetermined horizontal position, wherein each support device together with the respective at least one limiting device forms a carrier plate holding volume for holding at least one carrier plate in the predetermined horizontal position on the support plane, wherein the holding plate has, for each carrier plate holding volume, a pin holding volume adjacent below the respective carrier plate holding volume and the support plane for at least partially holding pins of the electronic components inserted through the carrier plate, and wherein the holding plate comprises, for each carrier plate holding volume, at least one fastening device for fastening the respective carrier plate in the respective carrier plate holding volume.

2. The holding plate according to claim 1,
wherein,
a respective horizontal extension of the at least two pin holding volumes corresponds to at least 50%, in particular at least 75%, 85% or at least 95%, of a horizontal extension of the respective carrier plate holding volume.

3. The holding plate according to claim 1,
wherein,
the at least two limiting devices are each designed as at least one projection on and/or as a recess in the holding plate, in particular monolithic and/or firmly bonded.

4. The holding plate according to claim 1,
wherein,
at least one of the support devices comprises at least one depth positioning device for the defined holding and vertical positioning of the respective carrier plate and/or at least one of the carrier plate holding volumes and/or the pin holding volumes are formed in one piece, as a pocket volume and/or as a continuous cut-out in the holding plate.

5. The holding plate according to claim 1,
wherein,
at least one of the pin holding volumes is arranged centrally and/or centered relative to the respective carrier plate holding volume and/or is evenly spaced relative to the respective carrier plate holding volume.

6. The holding plate according to claim 1,
wherein,
the at least two carrier plate holding volumes and/or limiting devices are rectangular,
in particular square, in particular wherein the at least two limiting devices each comprise at least one corner recess and/or
the at least two carrier plate holding volumes are arranged within a common plane, in particular parallel to an underside of the holding plate.

7. The holding plate according to claim 1,
wherein,
the holding plate comprises at least one ID device, wherein the ID device is designed for identification and/or for position detection of the holding plate by a pick and place machine.

8. A holding system for providing electronic components to a pick and place machine, the holding system comprising a holding plate and at least two carrier plates for electronic components,
wherein,
the holding plate is designed according to claim 1.

9. The holding system according to claim 8,
wherein,
at least one first carrier plate of the at least two carrier plates is designed to hold other electronic components than a second carrier plate of the at least two carrier plates, in particular, wherein the first carrier plate comprises at least one first plug and socket device for holding a first electronic component and wherein the second carrier plate comprises at least one second plug and socket device for holding a second electronic component, wherein the first plug and socket device and the second plug and socket device are designed differently.

10. The holding system according to claim 8,
wherein,
at least one of the at least two carrier plates comprises a support carrier plate, wherein the support carrier plate is fastened at a distance from and to the carrier plate, in particular wherein the support carrier plate has the same plug and socket devices as the carrier plate and/or wherein the support carrier plate has at least one frame device.

11. The holding system according to claim 8,
wherein,
at least one of the at least two carrier plates comprises at least one ID device, wherein the ID device is designed for identification and/or for position detection of the at least one carrier plate by a pick and place machine.

12. The holding system according to claim 8,
wherein,
the holding system is designed to carry out the provisioning method according to claim 15.

13. A use of a holding plate according to claim 1 for providing electronic components arranged on carrier plates to a pick and place machine for populating substrates with the electronic components.

14. A use of a holding system for providing electronic components arranged on carrier plates to a pick and place machine for populating substrates with electronic components,
wherein,
the holding system is designed according to claim 8, in particular wherein at least one first carrier plate of the at least two carrier plates is designed to hold different electronic components than a second carrier plate of the at least two carrier plates, in particular, wherein the first carrier plate comprises at least one first plug and socket device for holding a first electronic component and wherein the second carrier plate comprises at least one second plug and socket device for holding a second electronic component, wherein the first plug and socket device and the second plug and socket device are designed differently.

15. A provisioning method for providing electronic components to a pick and place machine through a holding plate, comprising the provisioning method:
providing at least one holding plate according to claim 1,
populating at least two carrier plates with different electronic components,
inserting the at least two carrier plates into the at least two carrier plate holding volumes of the at least one holding plate,
fastening of the at least two carrier plates to the holding plate by at least one fastening device of the holding plate in each case,
providing the electronic components to a pick and place machine through the holding plate.

16. A provisioning method for providing electronic components to a pick and place machine through a holding plate, comprising the provisioning method:
providing a holding system according to claim 8,
populating at least two carrier plates with different electronic components,
inserting the at least two carrier plates into the at least two carrier plate holding volumes of the at least one holding plate,
fastening of the at least two carrier plates to the holding plate by at least one fastening device of the holding plate in each case,
providing the electronic components to a pick and place machine through the holding plate.
